(19) United States
(12) Patent Application Publication
(10) Pub. No.: US 2002/0039807 A1
(43) Pub. Date: Apr. 4, 2002

(54) Manufacturing method of a semiconductor device

(75) Inventor: Toshiki Koyama, Kanagawa (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 09/969,221

(22) Filed: Oct. 2, 2001

(30) Foreign Application Priority Data
Oct. 3, 2000 (JP) P2000-303019

(51) Int. Cl. H01L 21/48; H01L 21/50; H01L 21/44

(52) U.S. Cl. 438/106; 438/113; 438/110; 438/611

(57) ABSTRACT

After interposer corresponding to respective device units are mounted on only good semiconductor chips of a semiconductor wafer and inner bumps of each interposer are joined to electrode pads of the associated good semiconductor chip by thermocompression bonding, the semiconductor wafer is cut into semiconductor chips to produce desired LGA semiconductor devices in each of which a good semiconductor chip is packaged on an interposer. Since the plane size of the interposer is equal to or smaller than that of the semiconductor chips, a real-chip-size semiconductor device can easily be realized.

### BACKGROUND OF THE INVENTION

1. Field of the Invention

The present invention relates to a manufacturing method of a semiconductor device. In particular, the invention relates to a manufacturing method of a semiconductor device in which a semiconductor integrated circuit chip (hereinafter referred to simply as “semiconductor chip”) is packaged on an interposer.

2. Description of the Related Art

A conventional manufacturing method of a semiconductor device in which a semiconductor chip is packaged on an interposer having wiring that is held by an insulating film such as a tape (first conventional manufacturing method of a semiconductor device) will be described for a BGA (ball grid array) device in which ball-shaped electrodes as external connection terminals are arranged in grid form on the back surface of the interposer, that is, a surface to be bonded to a printed circuit surface.

First, an interposer 30 shown in FIG. 7 is prepared. In the interposer 30, a circuit is formed by wiring layers 32 made of a conductive material such as copper that are formed on one surface of an insulating tape 31 made of polyimide or the like for each device unit corresponding to one semiconductor chip. An insulating film 33 is formed in each semiconductor chip mounting area so as to cover the wiring layers 32 partially. The wiring layers 32 are exposed in bonding regions.

External connection portions 34 (holes) for leading out part of the wiring layers 32 to establish external connections are formed at prescribed positions through the insulating tape 31.

On the other hand, as shown in FIG. 8, semiconductor chips 36 are cut out of a semiconductor wafer 35 with a diamond blade or the like. Usually, this step is called a dicing step.

Then, as shown in FIG. 9, each semiconductor chip 36 that was cut out of the semiconductor wafer 35 is mounted on the associated insulating film 33 which is formed in the associated semiconductor chip mounting area of the interposer 30 and the former is bonded to the latter with a die bonding material 37. Usually, this step is called a die bonding step.

Then, as shown in FIG. 10, on a heat column (not shown) being heated, electrode pads (not shown) that are formed on the surface of each semiconductor chip 36 are connected to wiring layers 32 in bonding regions of the interposer 30 by bonding wires 38 made of gold or the like. Usually, this step is called a wire bonding step.

Then, as shown in FIG. 11, each semiconductor chip 36 and its neighborhood are sealed with a molding resin 39 such as an epoxy resin. Usually, this step is called a molding step.

The method of the molding step is generally classified into two methods. In the first method, the interposer 30 is mounted in a molding die being heated and a melted molding resin is injected into the molding die through its gate. In the second method, a liquid molding resin is dropped and then set by heating.

Then, as shown in FIG. 12, solder ball electrodes 40 as external connection terminals are formed so as to fill in the respective external connection portions 34 formed in the insulating tape 31 of the interposer 30 and as to be connected to the respective wiring layers 32. Usually, this step is called a ball attaching step.

Then, as shown in FIG. 13, the interposer 30 is cut into pieces that correspond to the respective semiconductor chips 36 that are sealed with the molding resin 39. Usually, this step is called an outline cutting (cutting into pieces) step.

A desired BGA semiconductor device is formed by executing the steps of FIGS. 7-13.

Although the above manufacturing method is directed to a BGA device having the solder ball electrodes 40 as external connection terminals, an LGA (land grid array) device in which lands made of copper, gold, or the like as external connection terminals are formed on an interposer in advance can be manufactured by a similar manner. In the latter case, the ball attaching step for forming solder ball electrodes 40 is omitted.

However, in the first conventional manufacturing method of a semiconductor device, the electrode pads of each semiconductor chip 36 mounted on the interposer 30 are connected to wiring layers 32 of the interposer 30 by the bonding wires 38. Therefore, the molding resin 39 becomes thick due to bending of the bonding wires 38 and other factors and bonding regions need to be formed outside each semiconductor chip 36, which increase the size of semiconductor devices manufactured.

To decrease the size of semiconductor devices and simply the assembling process, the following manufacturing method of a semiconductor device (second conventional manufacturing method of a semiconductor device) has been proposed.

First, an interposer 50 shown in FIG. 14 is prepared. In the interposer 50, a circuit is formed by wiring layers 52 made of a conductive material such as copper that are formed on one surface of an insulating tape 51 made of polyimide or the like for each device unit corresponding to one semiconductor chip. In each semiconductor chip mounting area, inner bumps 53 are formed so as to correspond to respective electrode pads formed on the surface of each semiconductor chip and as to be connected to wiring layers 52.

An adhesive 54 is applied to the one surface of the insulating tape 51 and the wiring layers 52 excluding the inner bumps 53. That is, the top portions of the inner bumps 53 project from the adhesive layer 54 and are thereby exposed. Bump-shaped lands 55 as external connection terminals are formed on the other surface of the insulating tape 31 so as to be connected to respective wiring layers 32 through holes that are formed at prescribed positions.

On the other hand, as shown in FIG. 15 semiconductor chips 57 are cut out of a semiconductor wafer 56 with a diamond blade or the like (dicing step).

Then, as shown in FIG. 16, each semiconductor chips 57 that was cut out of the semiconductor wafer 56 is mounted facedown on the associated semiconductor chip mounting area of the interposer 50, and then electrode pads 58 formed on the surface of each semiconductor chip 57 are bonded to inner bumps 53 of the interposer 50 by thermocompression bonding (flip-tip connection step).

In the above flip-tip bonding step, when the electrode pads 58 of each semiconductor chip 57 is bonded to inner bumps 53 of the interposer 50 by thermocompression bonding, the adhesive 54 applied to the wiring layers 52 etc. of the interposer 50 secures mechanical and chemical bonding between each semiconductor chip 57 and the interposer 50, reinforces the metallurgical and electrical junctions between the electrode pads 58 of each semiconductor chip 57 and the inner bumps 53 of the interposer 50, and fills in the gap between each semiconductor chip 57 and the interposer 50. That is, the adhesive 54 also plays the role of a molding resin.

Then, as shown in FIG. 17, the interposer 50 is cut and separated into pieces having a prescribed package external size that correspond to the respective semiconductor chips 57 (outline cutting (cutting into pieces) step).

A desired LGA semiconductor device is formed by executing the steps of FIGS. 14-17.

In the second conventional manufacturing method of a semiconductor device, in contrast to the first conventional manufacturing method of a semiconductor device, it is not necessary to connect the electrode pads 58 of each semiconductor chip 57 mounted on the interposer 50 to the wiring layers 52 of the interposer 50 by bonding wires, whereby the size of semiconductor devices manufactured is smaller. Further, the assembling process is made so much simpler as omission of the wire bonding step etc.

To decrease the size of semiconductor devices and increase the efficiency of the assembling process, the following manufacturing method of a semiconductor device (third conventional manufacturing method of a semiconductor device) has been proposed as disclosed in Japanese Patent Laid-Open No. 303151/1998.

First, a semiconductor wafer 60 shown in FIG. 18A is prepared. The semiconductor wafer 60 is formed with a plurality of semiconductor chips 61. A plurality of solder bumps 62 are formed on the surface of each semiconductor chip 61 in a prescribed pattern.

On the other hand, an interposer 63 shown in FIG. 18B is prepared. Grid-like lines 64 are formed on the surface of the interposer 63 so as to produce sections having the same size as the semiconductor chips 61. A plurality of lands 65 are also formed on the surface of the interposer 63 in a prescribed pattern so as to correspond to the respective solder bumps 62 on the surface of each semiconductor chip 61.

Then, as shown in Fig. 19, after flux (not shown) is applied to the surface of the interposer 63, the solder bumps 62 of the semiconductor chips 61 of the semiconductor wafer 60 are positioned relative to the respective lands 65 of the interposer 63 and the semiconductor wafer 60 is mounted facedown on the interposer 63.

Then, the solder bumps 62 and the lands 65 are melted by a reflow treatment and the semiconductor wafer 60 is flip-tip-bonded to the interposer 63. Subsequently, the flux on the interposer 63 is removed by cleaning.

Then, as shown in FIG. 20, the tip of a nozzle 66 is inserted between the semiconductor wafer 60 and the interposer 63 and a sealing member 67 made of an epoxy resin or the like is supplied to the space in between. After the space between the semiconductor wafer 60 and the interposer 63 is charged with the sealing member 67, the sealing member 67 is set thermally by a heat treatment.

Then, as shown in FIGS. 21 and 22, an integral structure of the semiconductor wafer 60 and the interposer 63 is moved so as to be located above a dicing sheet 68 and is cut and separated into pieces with a dicing blade 69. That is, the semiconductor wafer 60 is separated into the semiconductor chips 61, and the interposer 63 is cut along the grid-like lines 64 and thereby separated into pieces having the same size as the semiconductor chips 61.

In this manner, integral structures of a semiconductor chip 61 and an interposer 63 that have a prescribed package outline size are cut out.

Then, as shown in FIG. 23, solder ball electrodes 70 as external connection terminals are formed in a prescribed pattern on the back surface of each interposer 63 of each cut-out integral structure having the prescribed package outline size so as to be electrically connected to lands 65 on the front surface of the interposer 63 through through-holes (not shown).

A desired BGA semiconductor device is formed by executing the steps of FIGS. 18A and 18B to FIG. 23.

In the third conventional manufacturing method of a semiconductor device, as in the case of the second conventional manufacturing method of a semiconductor device, it is not necessary to connect the electrode pads of each semiconductor chip 57 mounted on the interposer to the wiring layers of the interposer by bonding wires, whereby the size of semiconductor devices manufactured is smaller. Further, the assembling process is made so much simpler as omission of the wire bonding step etc.

However, even the second and third manufacturing methods capable of reducing the size of semiconductor devices manufactured and simplifying the assembling process because of improvements from the first conventional manufacturing method have several problems.

The following problems arise with the second conventional manufacturing method of FIGS. 14-17 when it is intended to make a semiconductor chip thinner or realize what is called a real-chip-size package in which the package outline size of a semiconductor device is almost equal to the plane size of a semiconductor chip to satisfy the recent requirements of further reduction in size and thickness on semiconductor devices.

(1) To cut the interposer 50 without damaging the semiconductor chips 57 in the outline cutting (cutting into pieces) step shown in FIG. 17, a clearance is needed between the semiconductor chips 57 and a cutting means such as a punch or laser light. Therefore, as shown in FIG. 17, the plane size of the interposer 50 is larger than that of the semiconductor chips 57 by the total length of clearance regions 59. It is difficult to realize a real-chip-size semiconductor device.

(2) To make the semiconductor devices 57 thinner, it is necessary to thin the semiconductor wafer 56 itself by grinding it. However, in this case, it becomes difficult to transport or handle the thinned semiconductor device 56 and the semiconductor chips 57 become prone to chip off during dicing of the thinned semiconductor wafer 56.

The third conventional manufacturing method of FIGS. 18A and 18B to FIG. 23, in which integral structures of a semiconductor chip 61 and an interposer 63 that have a prescribed package outline size are cut out of an integral structure of the semiconductor wafer 60 and the interposer 63, has the following problems though a real-chip-size semiconductor device can easily be realized.

(1) As shown in FIG. 18A, it is necessary to form a plurality of solder bumps 62 in a prescribed pattern on the surface of each semiconductor chip 61 of the semiconductor wafer 60. Therefore, a solder bump forming step which is not included in an ordinary wafer process needs to be added.

Further, where the wafer process and the assembling process are executed by different companies and the company in charge of the wafer process does not have a solder bump forming technique, the company in charge of the assembling process needs to do cumbersome work; for example, it needs to obtain various wafer data that are necessary for solder bump formation from the company in charge of the wafer process.

(2) Since the entire semiconductor wafer 60 is processed each time, even a semiconductor chip 61 that was judged defective by a wafer test that was performed after completion of the wafer process needs to be subjected to all the steps from the formation of solder bumps 62 to cutting an integral structure of the semiconductor wafer 60 and the interposer 63 into integral structures of a semiconductor chip 61 and an interposer 63 that have a prescribed package outline size. Various members are used in vain.

In particular, when the proportion of semiconductor chips 61 of a semiconductor wafer 60 that are judged good, that is, the yield of semiconductor chips 61, is low, using various members in vain means a great loss and hence causes cost increase.

### SUMMARY OF THE INVENTION

The present invention has been made in view of the problems of the above conventional manufacturing methods of a semiconductor device, and an object of the invention is therefore to provide a manufacturing method of a semiconductor device capable of simplifying and increasing the efficiency of a manufacturing process as well as reducing the size of a semiconductor device.

The above object is attained by a manufacturing method of a semiconductor device comprising a first step of forming interposer corresponding to respective device units in such a manner that inner bumps are formed on one major surface of a sheet-like insulator in each of the interposer; a second step of mounting the interposer on respective good semiconductor chips among semiconductor chips of a semiconductor wafer and joining the inner bumps of each of the interposer to electrodes of an associated good semiconductor chip of a semiconductor wafer; and a third step of cutting the semiconductor wafer into the semiconductor chips to produce semiconductor devices in each of which a good semiconductor chip is packaged on an interposer.

The term “good semiconductor chip” means a semiconductor chip that has been judged good in a wafer test that is performed on a semiconductor wafer that was subjected to a wafer process.

In this manufacturing method of a semiconductor device, after the interposer corresponding to respective device units are mounted on the good semiconductor chips of the semiconductor wafer and the inner bumps of each interposer are joined to the electrodes of the associated good semiconductor chip, the semiconductor wafer is cut into the semiconductor chips to produce semiconductor devices in each of which a good semiconductor chip is packaged on an interposer. Therefore, the assembling process is simplified and increased inefficiency. Further, the package outline size of a semiconductor device can easily be made a real chip size by making the plane size of the interposer equal to or smaller than that of the semiconductor chips.

Since the interposer corresponding to respective device units are mounted on only the good semiconductor chips of the semiconductor wafer, defective semiconductor chips are not processed at all. Therefore, the interposer are not used in vain, which contributes to cost reduction.

Forming the inner bumps on each interposer makes it unnecessary to form solder bumps on the surface of each semiconductor chip of the semiconductor wafer, which eliminates the need for adding a solder bump forming step that is not included in an ordinary wafer process. Therefore, even where the wafer process and the assembling process are executed by different companies, cumbersome work such as sending various wafer data that are necessary for formation of solder bumps from the company in charge of the wafer process to the company in charge of the assembling process need not be done.

Particularly in the case of manufacturing an LGA semiconductor device which uses lands as external connection terminals, it is preferable to form, in the first step, external connection terminals on the other major surface of the sheet-like insulator so that the external connection terminals are electrically connected to the respective inner bumps via wiring lines.

Particularly in the case of manufacturing a BGA semiconductor device which uses ball-shaped electrodes as external connection terminals, it is preferable to form such external connection terminals after the second step, that is, after the interposer were mounted on the respective good semiconductor chips of the semiconductor wafer and the inner bumps of each interposer were joined to the electrodes of the associated good semiconductor chip of the semiconductor chip, or after the third step, that is, after the semiconductor wafer was cut and the good semiconductor chips that had been bonded to the respective interposer were separated from each other.

It is preferable to bond the interposer to the respective good semiconductor chips of the semiconductor wafer via an adhesive that was applied in advance to the one major surface of the sheet-like insulator of each of the interposer, when the interposer are mounted on the respective good semiconductor chips of the semiconductor wafer in the second step.

In this case, not only can good bonding between the interposer and the respective good semiconductor chips of the semiconductor wafer be secured but also the mechanical and electrical junctions between the inner bumps of each interposer and the electrodes of the associated good semiconductor chip of the semiconductor wafer can be reinforced. These advantages contribute to increase of the reliability of semiconductor devices manufactured.

In the above case, it is preferable that the adhesive fill in the gap between each of the interposer and the associated good semiconductor chips of the semiconductor wafer.

With this measure, since an ordinary sealing step using a molding resin is omitted, the assembling process is simplified and increased in efficiency.

### BRIEF DESCRIPTION OF THE DRAWINGS

FIGS. 1A-1C are a schematic sectional view, a schematic top view, and a schematic bottom view of an interposer showing a first step of a manufacturing method of an LGA semiconductor device according to an embodiment of the invention;

FIGS. 2-6 are schematic process diagrams showing the other steps of the manufacturing method of an LGA semiconductor device according to the embodiment of the invention;

FIGS. 7-13 are schematic process diagrams showing a first conventional manufacturing method of a semiconductor device;

FIGS. 14-17 are schematic process diagrams showing a second conventional manufacturing method of a semiconductor device; and

FIGS. 18A and 18B to FIG. 23 schematic process diagrams showing a third conventional manufacturing method of a semiconductor device.

### DESCRIPTION OF THE PREFERRED EMBODIMENT

An embodiment of the present invention will be hereinafter described with reference to the accompanying drawings.

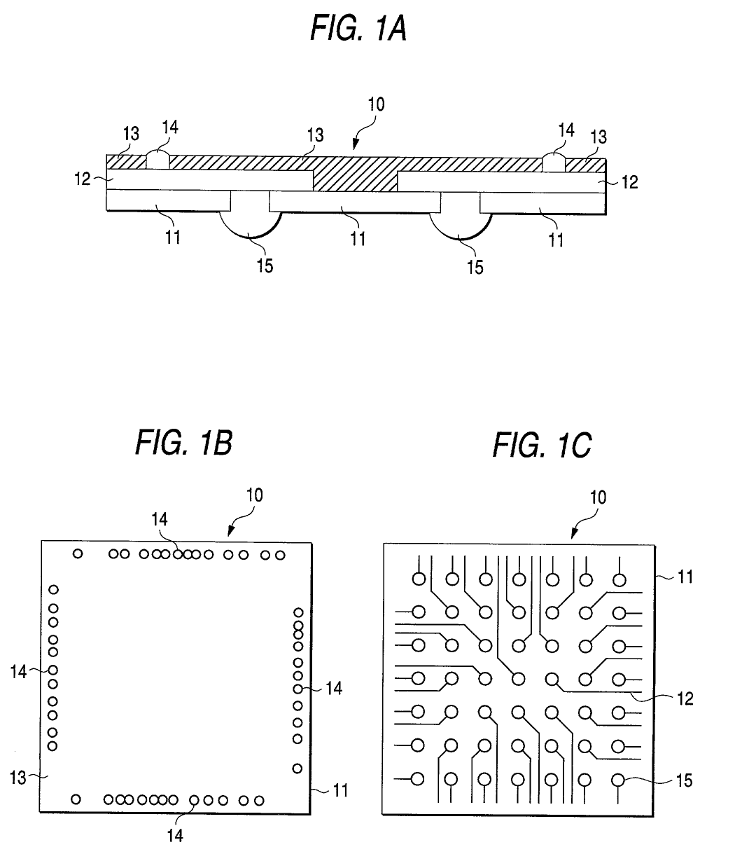

FIGS. 1A-1C to 6 are schematic process diagrams showing a manufacturing method of an LGA semiconductor device according to an embodiment of the invention.

(1) Interposer forming step (FIGS. 1A-1C)

First, interposer 10 corresponding to respective device units are prepared as shown in FIGS. 1A-1C. FIGS. 1A-1C are a schematic sectional view, a schematic top view, and a schematic bottom view of an interposer 10.

The interposer 10 corresponding to respective device units are produced in the following manner.

A prescribed circuit is formed by forming wiring layers 12 made of a conductive material such as copper on one major surface of, for example, a base film 11 as a sheet-like insulator. After an adhesive 13 is applied to the one major surface of the base film 11 and the wiring layers 12, through-holes are formed through the adhesive 13 at prescribed positions to expose the wiring layers 12 partially. Through-holes are also formed through the base film 11 at prescribed positions to expose the wiring layers 12 partially.

Then, inner bumps 14 and bump-shaped lands 15 as external connection terminals are formed on both sides by growing copper, for example, by electroplating or the like so that it is connected to the wiring layers 12 through the two kinds of through-holes. Then, gold plating layers (not shown) are formed on the surfaces of the inner bumps 14 and the bump-shaped lands 15, respectively. Nickel plating layers may be formed under the respective gold plating layers.

In this manner, an interposer is formed in which the inner bumps 14 that are connected to wiring layers 12 are formed on the one major surface of the base film 11 and the bump-shaped lands 15 as external connection terminals that are connected to wiring layers 12 are formed on the other major surface of the base film 11.

Then, the interposer is cut into pieces having a prescribed shape, that is, interposer 10 corresponding to respective device units that correspond to respective semiconductor chips. At this time, the plane size of the interposer 10 corresponding to respective device units is set equal to or smaller than that of the semiconductor chips.

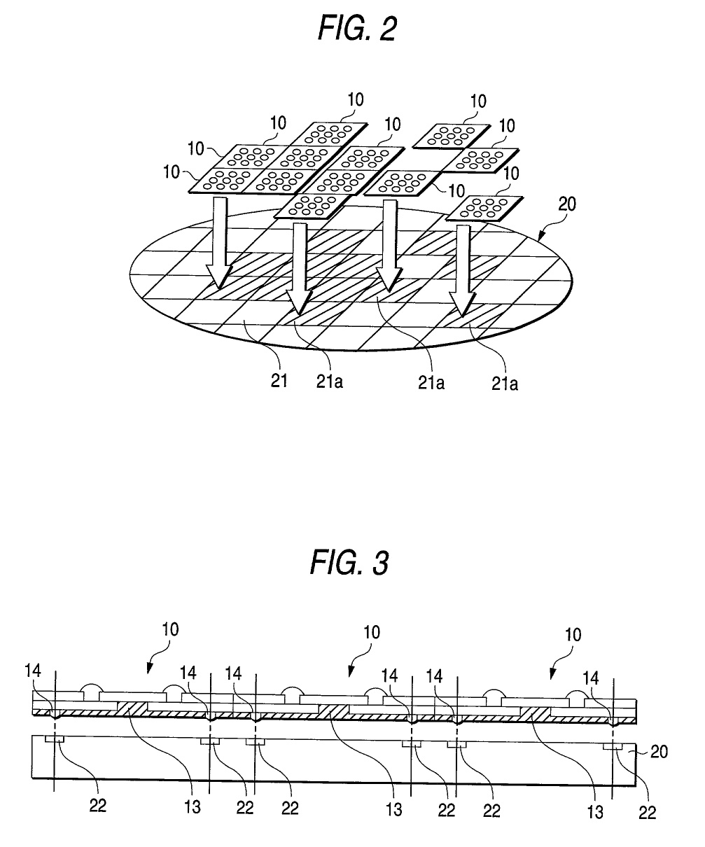

(2) Step of mounting interposers on semiconductor wafer (FIGS. 2-4)

First, a wafer test is performed in which semiconductor chips 21 are judged good or defective by bringing probe needles into contact with electrode pads 22 of each semiconductor chip 21 of a semiconductor wafer 20 that has been subjected to a wafer process. Interposer l0 corresponding to respective device units are mounted on only the semiconductor chips 21 that have been judged good (hereinafter referred to as “good semiconductor chips 21a”) of the semiconductor wafer 20.

This step will be described below in more detail.

As shown in FIG. 3, after an interposer 10 corresponding to respective device units is transported so as to be located above a good semiconductor chip 21a of the semiconductor wafer 20, positioning is performed so that the centers of the inner bumps 14 of the interposer 10 are aligned with the centers of the electrode pads 22 of the good semiconductor chip 21a, respectively, as indicated by one-dot chain lines in FIG. 3.

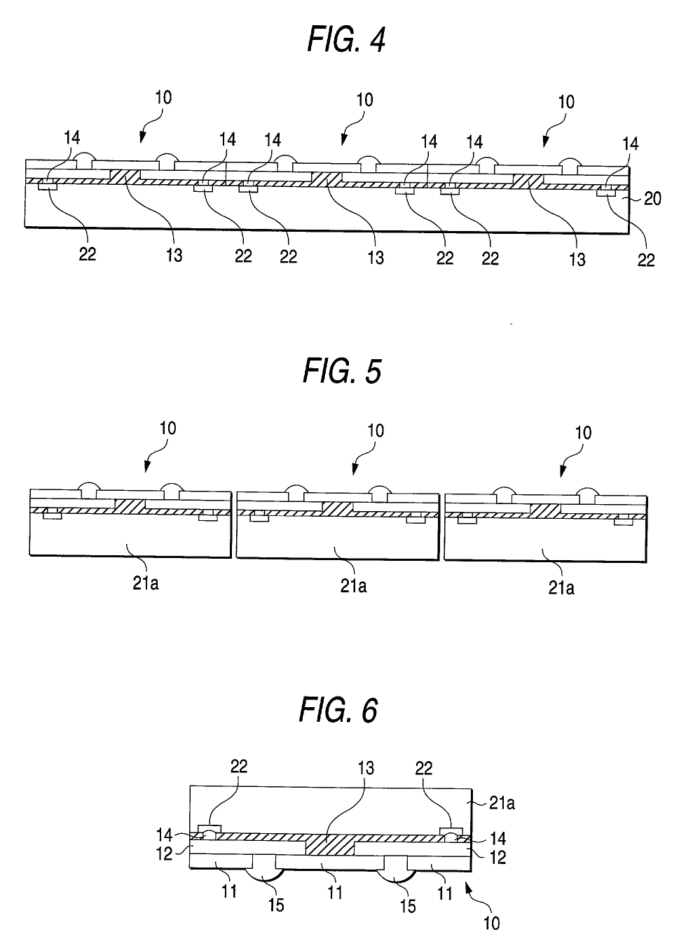

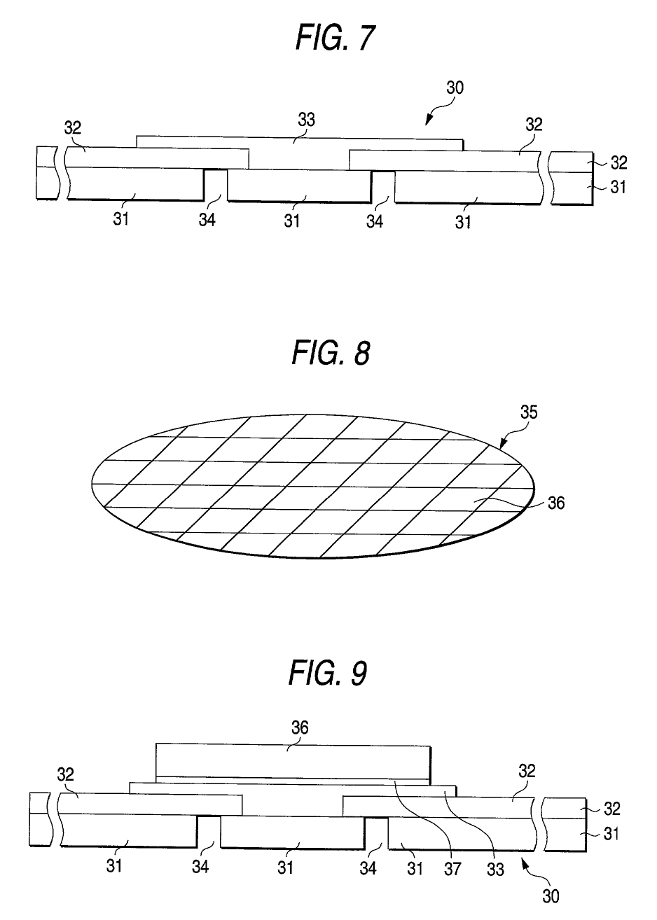

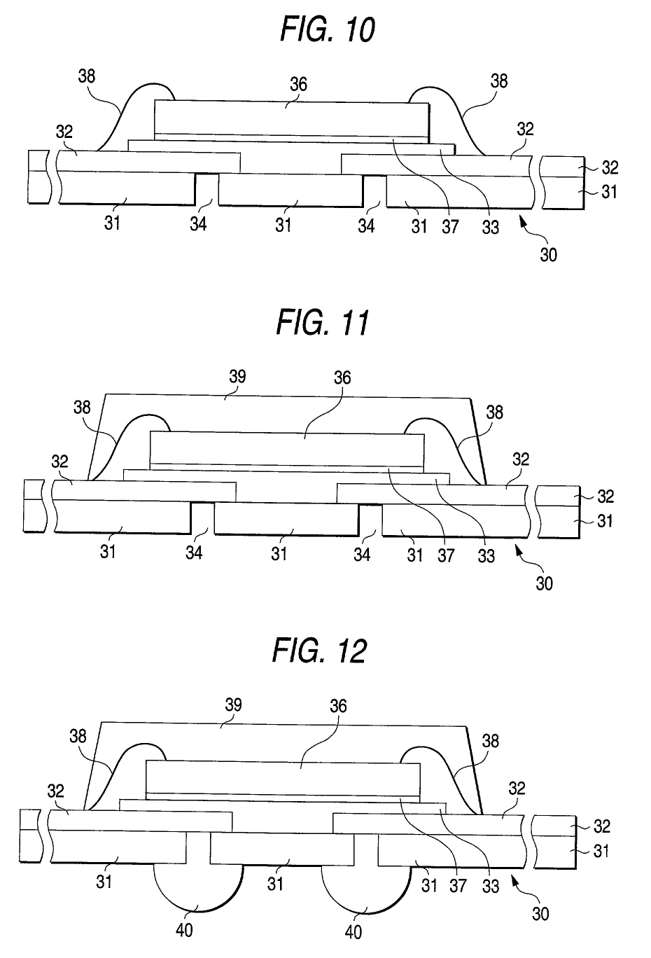

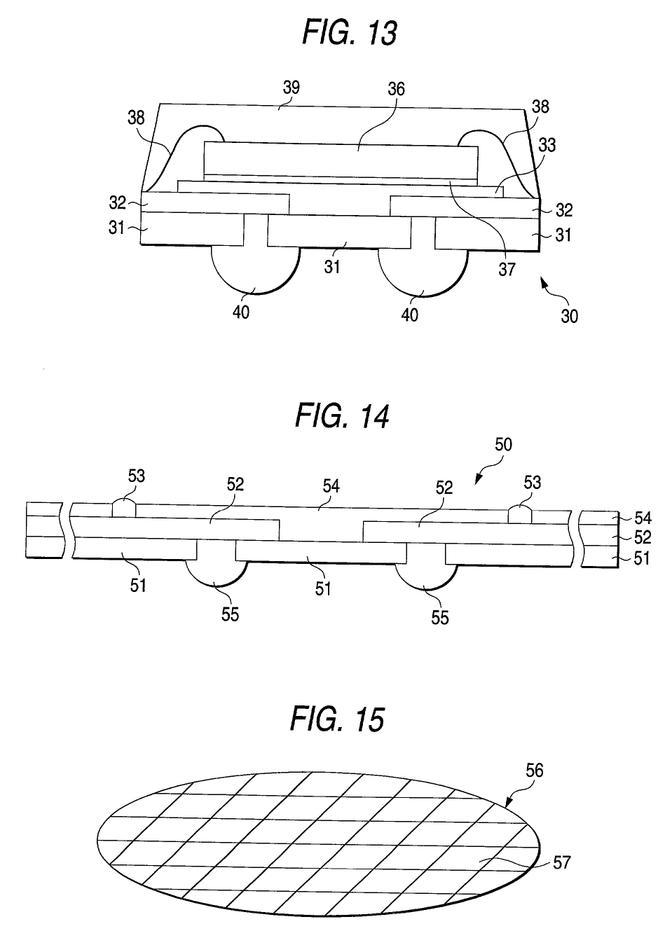

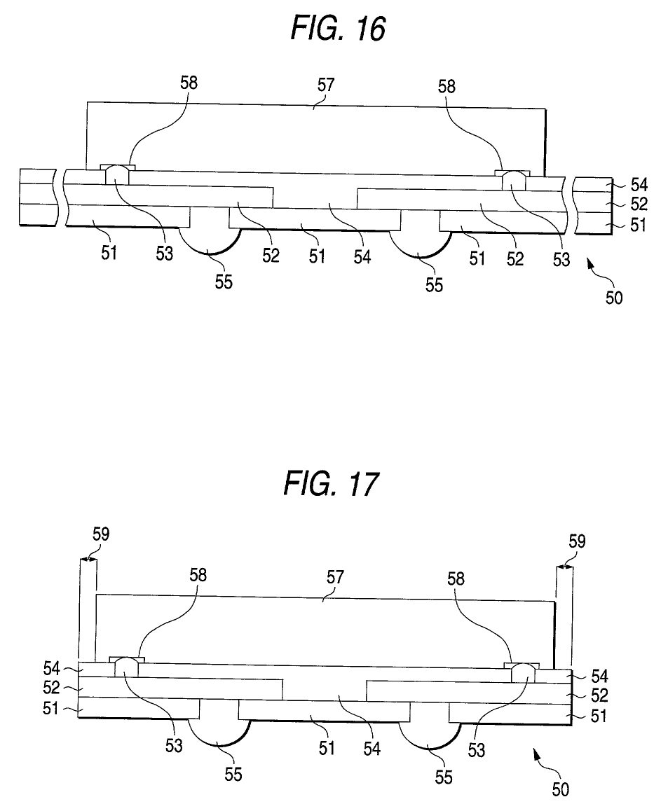

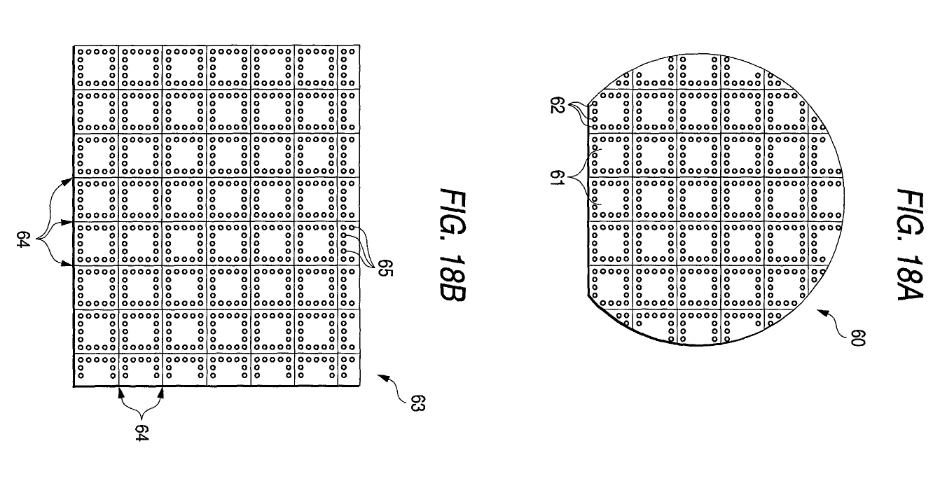

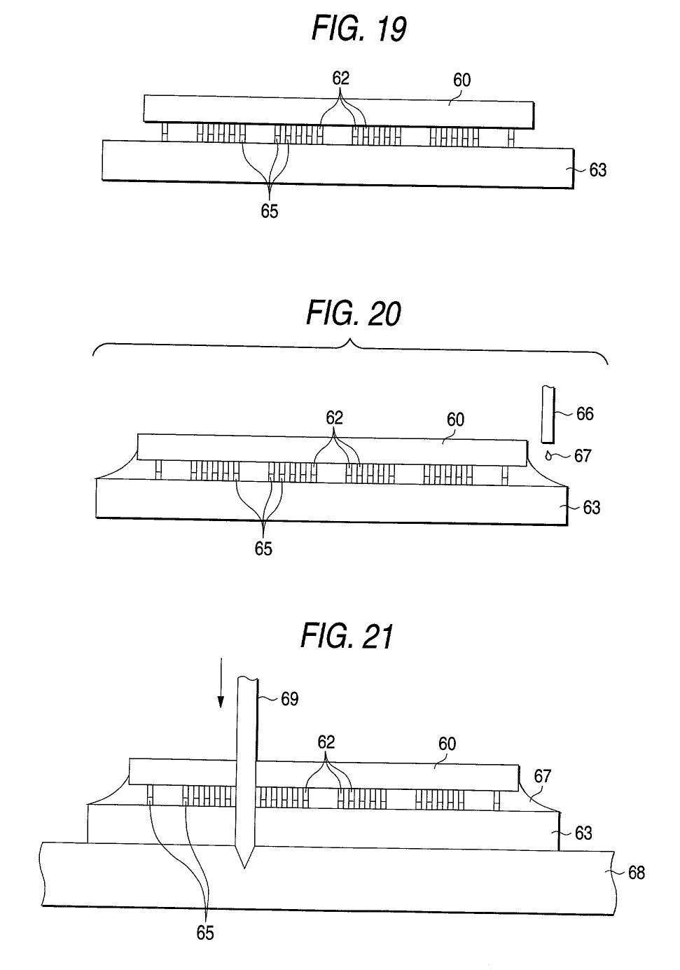

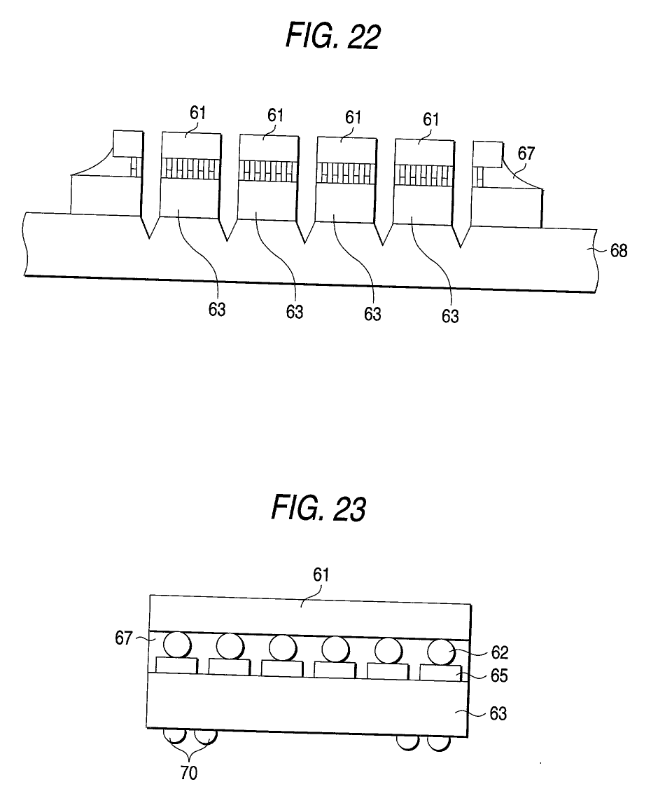

Then, as shown in FIG. 4, the interposer 10 is lowered and the inner bumps 14 of the interposer 10 and the electrode pads 22 of the good semiconductor chip 21a are subjected to thermocompression bonding by applying pulsed heat of 350-400° C., for example, to those, whereby the inner bumps 14 are joined to the electrode pads 22 mechanically and electrically.

When the inner bumps 14 of the interposer 10 are bonded to the electrode pads 22 of the good semiconductor chip 21a by thermocompression bonding, the adhesive 13 applied to the one major surface of the base film 11 and the wiring layers 12 expands temporarily and then contracts due to temperature reduction. Therefore, the adhesive 13 secures good bonding between the interposer 10 and the good semiconductor chip 21a and reinforces the mechanical and electrical junctions between the inner bumps 14 of the interposer 10 and the electrode pads 22 of the good semiconductor chip 21a.

Further, playing the role of a molding resin, the adhesive 13 completely fills in the gap between the interposer 10 and the good semiconductor chip 21a.

(3) Semiconductor wafer dicing (cutting into pieces) step (FIGS. 5 and 6)

As shown in FIG. 5, the semiconductor wafer 20 is cut at prescribed positions with a diamond blade or the like in the same manner as in the conventional dicing step and is thereby separated into the semiconductor chips 21. That is, the good semiconductor chips 21a that are mounted with the respective interposer 10 are cut out.

Then, as shown in FIG. 6, each good semiconductor device 21a shown in FIG. 5 that has been cut out of the semiconductor wafer 20 is turned upside down, where by a desired LGA semiconductor device is completed in which the good semiconductor chip 21a is packaged on an interposer 10.

As described above, according to the above embodiment, after the interposer 10 corresponding to respective device units are mounted on the good semiconductor chips 21a of the semiconductor wafer 20 and the inner bumps 14 of each interposer 10 are joined to the electrode pads 22 of the associated good semiconductor chip 21a by thermocompression bonding, the semiconductor wafer 20 is cut into the semiconductor chips 21 to produce desired LGA semiconductor devices in each of which a good semiconductor chip 21a is packaged on an interposer 10. Therefore, the assembling process is simplified and increased in efficiency. Further, since the plane size of the interposer 10 is equal to or smaller than that of the semiconductor chips 21, a real-chip-size semiconductor device can easily be realized. Therefore, the embodiment enables cost reduction and contributes to size reduction of a semiconductor device.

Since defective ones among the semiconductor chips 21 of the semiconductor wafer 20 are not processed at all, the interposer 10 are not used in vain, which contributes to cost reduction.

Forming the inner bumps 14 on each interposer 10 makes it unnecessary to form bumps on the surface of each semiconductor chip 21 of the semiconductor wafer 20, which eliminates the need for adding a solder bump forming step that is not included in an ordinary wafer process. Therefore, even where the wafer process and the assembling process are executed by different companies, cumbersome work such as sending various wafer data that are necessary for formation of bumps from the company in charge of the wafer process to the company in charge of the assembling process need not be done.

The adhesive 13 is applied in advance to each of the interposer 10. Therefore, when the interposer 10 are mounted on the respective good semiconductor chips 21a of the semiconductor wafer 20 and the inner bumps 14 of each interposer 10 are jointed to the electrode pads 22 of the associated good semiconductor chip 2la by thermocompression bonding, the adhesive 13 makes it possible to secure good bonding between the interposer 10 and the respective good semiconductor chips 21a and to reinforce the mechanical and electrical junctions between the inner bumps 14 of each interposer 10 and the electrode pads 22 of the associated good semiconductor chip 21a. These advantages contribute to increase of the reliability of semiconductor devices manufactured.

Since the adhesive 13 completely fills in the gap between each interposer 10 and the associated good semiconductor chip 21a, the reliability of semiconductor devices manufactured can be increased. Further, the assembling process can further be simplified and increased in efficiency by virtue of omission of an ordinary sealing step using a molding resin.

Although the embodiment is directed to the manufacturing method of the LGA semiconductor device using the bump-shaped lands 15 as external connection terminals, the invention can naturally be applied to a manufacturing method of a BGA semiconductor device which uses, as external connection terminals, ball-shaped electrodes such as solder balls.

In this case, ball-shaped electrodes as external connection electrodes may be formed after the interposer 10 were mounted on only the respective good semiconductor chips 21a of the semiconductor wafer 20 and the inner bumps 14 of each interposer 10 were joined to the electrode pads 22 of the associated good semiconductor chip 21a by thermocompression bonding, Alternatively, ball-shaped electrodes as external connection terminals may be formed after the semiconductor wafer 20 was cut and the good semiconductor chips 21a were thereby separated from each other to assume a state that each good semiconductor chip 21a is packaged on an interposer 10.

As described above in detail, the manufacturing method of a semiconductor device according to the invention provides the following advantages.

In the manufacturing method of a semiconductor device according to the invention, after interposer corresponding to respective device units are mounted on good semiconductor chips of a semiconductor wafer and inner bumps of each interposer are joined to electrodes of the associated good semiconductor chip, the semiconductor wafer is cut into semiconductor chips to produce semiconductor devices in each of which a good semiconductor chip is packaged on an interposer. Therefore, the assembling process is simplified and increased inefficiency. Further, the package outline size of a semiconductor device can easily be made a real chip size by making the plane size of the interposer equal to or smaller than that of the semiconductor chips. Therefore, the invention enables cost reduction and contributes to size reduction of a semiconductor device.

Since the interposer corresponding to respective device units are mounted on only the good semiconductor chips of the semiconductor wafer, defective semiconductor chips are not processed at all. Therefore, the interposer are not used in vain, which contributes to cost reduction.

What is claimed is:

1. A manufacturing method of a semiconductor device, comprising:
a first step of forming interposer corresponding to respective device units in such a manner that inner bumps are formed on one major surface of a sheet-like insulator in each of the interposer;
a second step of mounting the interposer on respective good semiconductor integrated circuit chips among semiconductor integrated circuit chips of a semiconductor wafer and joining the inner bumps of each of the interposer to electrodes of an associated good semiconductor integrated circuit chips; and
a third step of cutting the semiconductor wafer into the semiconductor integrated circuit chips to produce semiconductor devices in each of which a good semiconductor integrated circuit chip is packaged on an interposer.

2. The manufacturing method according to claim 1, wherein the first step further forms external connection terminals on the other major surface of the sheet-like insulator so that the external connection terminals are electrically connected to the respective inner bumps via wiring lines.

3. The manufacturing method according to claim 1, further comprising, after the second step, a step of forming external connection terminals on the other major surface of the sheet-like insulator of each of the interposer so that the external connection terminals are electrically connected to the respective inner bumps via wiring lines.

4. The manufacturing method according to claim 1, further comprising, after the third step, a step of forming external connection terminals on the other major surface of the sheet-like insulator of each of the interposer so that the external connection terminals are electrically connected to the respective inner bumps via wiring lines.

5. The manufacturing method according to claim 1, wherein the second step further bonds the interposer to the respective good semiconductor integrated circuit chips of the semiconductor wafer via an adhesive that was applied in advance to the one major surface of the sheet-like insulator of each of the interposer, when the interposer are mounted on the respective good semiconductor integrated circuit chips.

6. The manufacturing method according to claim 5, wherein the adhesive fills in a gap between each of the interposer and an associated good semiconductor integrated circuit chip.
